(19) United States
(12) Patent Application Publication
(10) Pub. No.: US 2024/0306365 A1
(43) Pub. Date: Sep. 12, 2024

(54) 3D CELL AND ARRAY STRUCTURES WITH PARALLEL BIT LINES AND SOURCE LINES

(71) Applicant: Fu-Chang Hsu, San Jose, CA (US)

(72) Inventor: Fu-Chang Hsu, San Jose, CA (US)

(21) Appl. No.: 18/597,866

(22) Filed: Mar. 6, 2024

Related U.S. Application Data
(60) Provisional application No. 63/450,361, filed on Mar. 6, 2023.
(60) Provisional application No. 63/450,961, filed on Mar. 9, 2023.
(60) Provisional application No. 63/451,832, filed on Mar. 13, 2023.
(60) Provisional application No. 63/467,321, filed on May 18, 2023.

(51) Int. Cl. H10B 12/00

(52) U.S. Cl. CPC H10B 12/20

(57) ABSTRACT

Various 3D cells, array structures with parallel bit lines and source lines are disclosed. In an embodiment, a 3D cell structure includes a vertical bit line (BL), a vertical source line (SL), a floating body surrounding the BL and the SL, an insulator surrounding the floating body, a first gate dielectric layer coupled to the insulator, the floating body, top portions of the BL and the SL, a second gate dielectric layer coupled to the insulator, the floating body, and bottom portions of the BL and the SL, a front gate connected to a top surface of the first gate dielectric layer, and a back gate connected to a bottom surface of the second gate dielectric layer.

### CROSS-REFERENCE TO RELATED APPLICATIONS

This application claims the benefit of priority under 35 U.S.C. 119(e) based upon U.S. Provisional Patent Application having Application No. 63/450,361 filed on Mar. 6, 2023, and entitled “3D Cell and Array Structures,” and U.S. Provisional Patent Application having Application No. 63/450,961 filed on Mar. 9, 2023, and entitled “3D Cell and Array Structures,” and U.S. Provisional Patent Application having Application No. 63/451,832 filed on Mar. 13, 2023, and entitled “3D Cell and Array Structures and Processes,” and U.S. Provisional Patent Application having Application No. 63/467,321 filed on May 18, 2023, and entitled “3D Cell and Array Structures,” all of which are incorporated by reference herein in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use three-dimensional (3D) array structures. The 3D array structure has been successfully used in NAND flash memory today. However, for NOR-type cell arrays, a cost-effective 3D array structure has not been realized. Due to mis-alignment issues, the cell structure in the bottom layers of 3D array structure may not be formed correctly.

### SUMMARY

In various exemplary embodiments, three-dimensional (3D) cells, array structures, and associated processes are disclosed. For example, embodiments of the invention are applicable to 3D NOR-type (or also called AND-type) cell and array structures. However, embodiments of the invention are applicable to many technologies. For example, embodiments of the invention can be applied to dynamic random-access memory (DRAM), floating-body cell (FBC) memory, NOR-type flash memory, Ferroelectric random-access memory (FRAM), resistive random-access memory (RRAM), phase change memory (PCM), magneto-resistive random-access memory (MRAM), split-gate NOR flash memory, memory array for in-memory computing (IMC), and memory elements called ‘synapses’ in artificial neural networks. In addition, embodiments of the invention are applicable to any other applications not listed and all such applications are within the scope of the invention.

In an exemplary embodiment, a three-dimensional (3D) array structure is provided that comprises a vertical bit line (BL), a vertical source line (SL), a floating body surrounding the BL and the SL, an insulator surrounding the floating body, a first gate dielectric layer coupled to the insulator, the floating body, top portions of the BL and the SL, a second gate dielectric layer coupled to the insulator, the floating body, and bottom portions of the BL and the SL, a front gate connected to a top surface of the first gate dielectric layer, and a back gate connected to a bottom surface of the second gate dielectric layer.

In an exemplary embodiment, a three-dimensional (3D) array structure is provided that comprises a vertical bit line (BL), a vertical source line (SL), a floating body surrounding and connected to a portion of the BL and a portion of the SL and filling any space in between the BL and SL, a gate dielectric layer coupled to and surrounding the floating body, a gate surrounding the gate dielectric layer, a first insulating layer coupled to a top surface of the gate dielectric layer and the floating body, and surrounding top portions of the BL and the SL, and a second insulating layer coupled to a bottom surface of the gate dielectric layer and the floating body, and surrounding bottom portions of the BL and the SL.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A shows an embodiment of a cell structure forming a 3D NOR-type (or also called AND-type) array according to the invention.

FIG. 1B shows the cell structure of FIG. 1A with a front gate and a gate dielectric layer removed.

FIG. 1C shows a top view of a horizontal cross-section taken along the line A-A′ shown in FIG. 1A.

FIG. 1D shows a top view of a horizontal cross-section taken along the line B-B′ line shown in FIG. 1A.

FIG. 1E shows an embodiment of a floating-body cell structure.

FIG. 1F shows an embodiment of a ferroelectric random-access memory (FRAM) or ferroelectric field-effect transistor (FeFET) cell structure.

FIG. 2A shows another embodiment of a cell structure for a 3D NOR-type (or also called AND-type) array according to the invention.

FIG. 2B shows a cross-section of the cell structure shown in FIG. 2A along the line A-A′.

FIG. 3A shows another embodiment of a cell structure for a 3D NOR-type (or also called AND-type) array according to the invention.

FIG. 3B shows a cross-section of the cell shown in FIG. 3A taken along the line A-A′.

FIG. 4A shows an embodiment of a 3D array structure using the cell structure shown in FIGS. 1A-D according to the invention.

FIG. 4B shows another embodiment of a 3D array structure according to the invention.

FIG. 4C shows another embodiment of a 3D array structure to the invention.

FIG. 5 shows another embodiment of a 3D array structure using the cell structure shown in FIGS. 3A-B according to the invention.

FIGS. 6A-H show an embodiment of process steps used to form the cell structure shown in FIGS. 1A-D according to the invention.

FIGS. 7A-B shows an embodiment of process steps used to form the cell structure shown in FIGS. 3A-B according to the invention.

FIGS. 8A-C show another embodiment of process steps to form the cell structure shown in FIGS. 2A-B according to the invention.

FIG. 9A shows another embodiment of a cell structure for a 3D NOR-type (or also called AND-type) array according to the invention.

FIG. 9B shows a detailed embodiment of a charge-trapping layer.

FIG. 10A shows an embodiment of a cell structure for a 3D NOR-type (or also called AND-type) array according to the invention.

FIG. 10B shows a detailed embodiment of a gate dielectric layer.

FIG. 11A shows an embodiment of a cell structure for a 3D NOR-type (or also called AND-type) array according to the invention.

FIG. 11B shows detailed embodiment of a gate dielectric layer.

FIG. 12A shows an embodiment of a cell structure for a 3D NOR-type (or also called AND-type) array according to the invention.

FIG. 12B shows detailed embodiment of the structure of a gate dielectric layer.

FIG. 13A shows an embodiment of a cell structure for a 3D NOR-type (or also called AND-type) array according to the invention.

FIG. 13B shows detailed embodiment of the structure of a gate dielectric layer.

FIG. 14A shows an embodiment of a cell structure for a 3D NOR-type (or also called AND-type) array according to the invention.

FIG. 14B shows detailed embodiment of the structure of a gate dielectric layer.

FIGS. 15A-C show comparisons of top views of three cell structures shown in FIG. 9A, FIG. 11A, and FIG. 13A, respectively.

FIGS. 16A-J shows an embodiment of process steps configured to form the cell structure shown in FIG. 11A according to the invention.

FIGS. 17A-D show an embodiment of process steps configured to form the cell structure shown in FIG. 11B according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, three-dimensional cells, array structures, and associated processes are disclosed. Embodiments of the invention are applicable to many technologies. For example, embodiments of the invention can be applied to dynamic random-access memory (DRAM), floating-body cell (FBC) memory, NOR-type flash memory, Ferroelectric random-access memory (FRAM), resistive random-access memory (RRAM), phase change memory (PCM), magneto-resistive random-access memory (MRAM), split-gate NOR flash memory, memory array for in-memory computing (IMC), and memory elements called ‘synapses’ in artificial neural networks. In addition, embodiments of the invention are applicable to any other applications not listed and all such applications are within the scope of the invention.

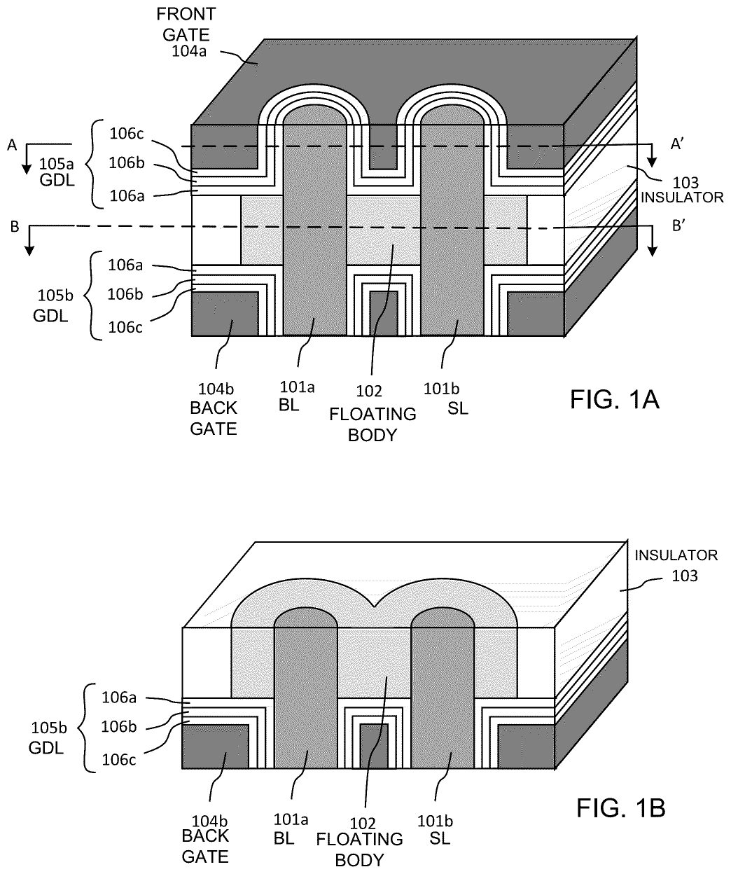

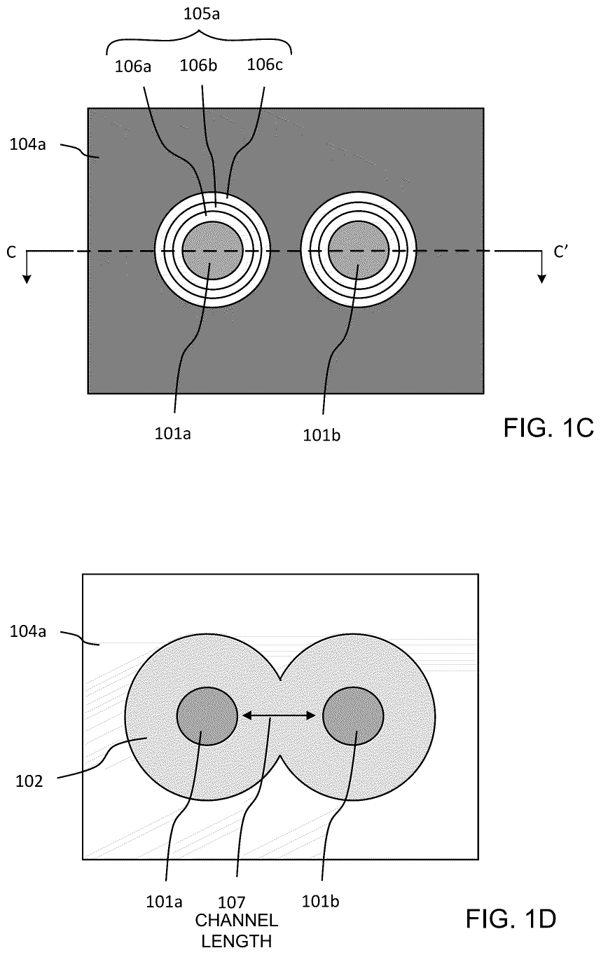

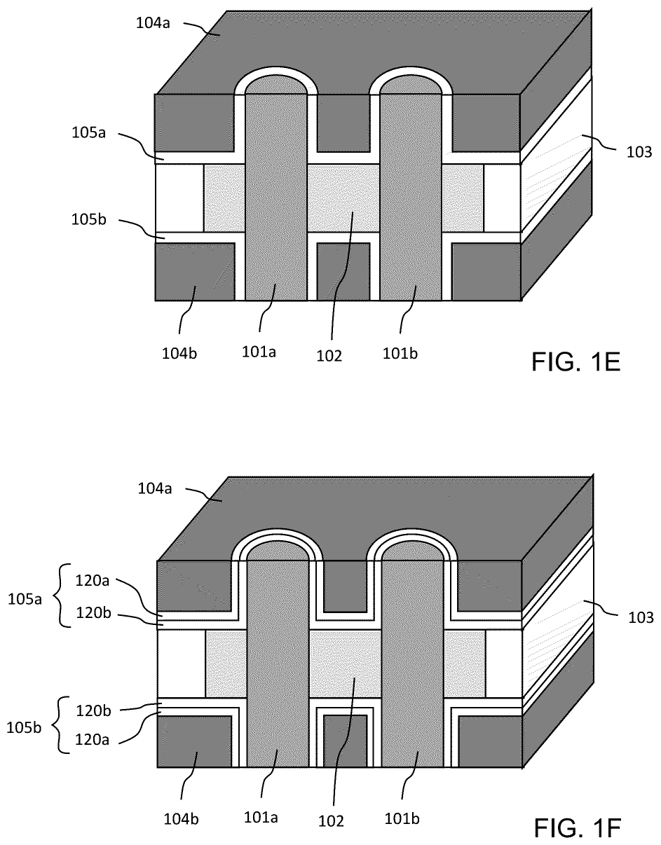

FIG. 1A shows an embodiment of a cell structure forming a 3D NOR-type (or also called AND-type) array according to the invention. The cell structure includes a bit line (BL) 101a and a source line (SL) 101b. In one embodiment, the BL 101a and SL 101b are formed of heavily doped semiconductor material, such as N+ or P+ polysilicon material. In another embodiment, a metal core is formed in the center of the bit line 101a and the source line 101b to reduce the resistances of the bit line 101a and the source line 101b.

The cell structure also includes a floating body 102 that is formed of semiconductor material. It should be noted that the semiconductor material used in all the embodiments of the celloxide-based disclosed herein can be any suitable semiconductor material, such as silicon (Si), polysilicon (Poly-Si), germanium (Ge), silicon germanium (SiGe), gallium (Ga), Arsenic (As), Indium (In), gallium nitride (GaN), gallium-arsenide (GaAs), indium silicon (InSi), germanium indium (Geln), indium gallium arsenide (InGaAs), silicon carbide (SiC), oxide based semiconductor such as Indium gallium zinc oxide (IGZO), or selected from many other semiconductor types. For simplicity, the embodiments shown will use silicon and polysilicon as example implementations. However, using any other semiconductor materials shall remain in the scope of the invention.

In one embodiment, the floating body 102 is lightly doped with the opposite type of doping from the bit line 101a and source line 101b. This configuration forms a junction transistor cell. In another embodiment, the floating body 102 is heavily doped with the same type of doping as the bit line 101a and source 101b. This configuration forms a junction-less transistor cell. In another embodiment, the floating body 102 is formed of doped semiconductor material and the bit line 101a and source line 101b are formed of metals. This configuration forms a Schottky-junction transistor cell.

The cell structure also includes an insulating layer 103 comprising material such as oxide or nitride material. A front gate 104a and a back gate are also provided. In one embodiment, the front gate 104a and the back gate 104b are formed of conductor material, such as metal or heavily doped polysilicon. In one embodiment, the front gate 104a and back gate 104b are connected to the gates of adjacent cells to form word lines (WL).

The cell structure also includes gate dielectric layers (GDL) 105a and 105b. Depending on the cell type and technology, the gate dielectric layer 105a and 105b are formed of different materials and structure. For example, in one embodiment of a floating body cell type dynamic random-access memory (DRAM) as shown in FIG. 1E, the gate dielectric layers 105a and 105b are formed of a thin oxide layer or Hi-K material layer such as hafnium oxide (HfO2). In another embodiment, such as the NOR-type flash memory shown in FIGS. 1A-B, the gate dielectric layers 105a and 105b are charge-trapping layers comprising material such as oxide-nitride-oxide (ONO) layers, oxide-nitride-oxide-nitride-oxide (ONONO) layers, or oxide-nitride (ON) layers.

FIG. 1B shows the cell structure of FIG. 1A with the front gate 104a and the gate dielectric layer 105a removed. The floating body 102 is formed as a donut shape as shown. Please notice, although the embodiment shows that the shapes of the bit line 101a, source line 101b, and the floating body 102 are circular, it is obvious that in other embodiments, these components are formed in any other shapes, such as squares, rectangles, triangles, hexagons, etc. These variations shall remain in the scope of the invention.

FIGS. 1A-B show an embodiment of the gate dielectric layers 105a and 105b using ONO layers. For example, the gate dielectric layer 105a and 105b comprise multiple layers 106a to 106c. The layer 106a is a tunnel oxide layer, which is thin enough to allow electrons to tunnel through when a high electric field is applied. The layer 106b is a nitride layer that may trap electrons or holes for data storage. The layer 106c is a blocking oxide which is thick enough to prevent electrons tunneling through to the front gate 104a and the back gate 104b. In another embodiment, the layer 106c is a tunnel oxide layer and the layer 106a is a blocking oxide layer. In this embodiment, during programming, the electrons or holes are injected from the selected front gate 104a or the back gate 104b to the nitride layer 106b.

Although ONO layers 106a, 106b, and 106c are used as an example of the charge-trapping layers, any number of nitride and oxide layers may be added in-between the layers 106a and 106c. For example, in another embodiment, enough layers are added to form oxide-nitride-oxide-nitride-oxide (ONONO) layers. These variations are within in the scope of the invention.

FIG. 1F shows an embodiment of a ferroelectric random-access memory (FRAM) or ferroelectric field-effect transistor (FeFET) cell. The gate dielectric layers 105a and 105b comprise a ferroelectric layer 120a and a dielectric layer 120b. The ferroelectric layer 120a comprises materials that have ferroelectric behavior, such as lead zirconate titanate (PZT), Hafnia-based ferroelectric materials, hafnium oxide (HfO2) in orthorhombic crystal phase, hafnium zirconium oxide (HfZrO), aluminum-doped hafnium oxide (HfO2), germanium-doped hafnium oxide (HfO2), silicon-doped hafnium oxide (HfO2), yttrium-doped hafnium oxide (HfO2), aluminum-doped hafnium oxide (HfO2), lead zirconium titanium bismuth iron oxide (PZT/BFO), and/or combinations of these materials.

The gate dielectric layer 120b or buffer layer comprises material such as thin oxide or high-K material such as hafnium oxide (HfO2). In various embodiments, the cell structure includes various structures of the dielectric layer 120b. In another embodiment, the dielectric layer 120b is eliminated so that the ferroelectric layer 120a directly contacts with the semiconductor layer 102. In another embodiment, a metal layer such as titanium or tungsten is formed in between the ferroelectric layer 120a and the dielectric layer 120b.

In another embodiment of resistive random-access memory (RRAM), the gate dielectric layers 105a and 105b are formed of an adjustable resistive layer such as hafnium oxide (HfOx), titanium oxide (TiOx), and tantalum oxide (TaOx). In another embodiment of phase-change memory (PCM), the gate dielectric layers 105a and 105b are formed of multiple layers comprising at least one phase-change layer such as Germanium Antimony Tellurium alloy or chalcogenide glass, Ge2Sb2Te5 (GST).

In another embodiment of a magneto resistive random-access memory (MRAM), the gate dielectric layers 105a and 105b comprise multiple layers including ferromagnetic material such as iron-nickle (NiFe) or iron-cobalt (CoFe) alloys. It should be noted that the materials of the gate dielectric layers 105a and 105b described are just some examples. Using any other suitable materials in the gate dielectric layers 105a and 105b shall remain within the scope of the invention.

FIG. 1C shows a horizontal cross-section view of the array structure shown in FIG. 1A taken along the line A-A′. The cross-section line C-C′ defines the cross-section view shown in FIG. 1A.

FIG. 1D shows a horizontal cross-section view of the array structure shown in FIG. 1A taken along the line B-B′. Also shown in FIG. 1D is a channel length 107 of the cell transistor, which is in the range of 1 nm (nanometer) to lum (micro-meter), however, any other channel lengths may be used.

FIG. 1E shows an embodiment of a floating-body cell structure. The floating body 102 stores electric charges such as electric holes or electrons to alter the threshold voltage (Vt) of the cell to represent data. For example, in one embodiment, the floating body is formed of P-type semiconductor material. The bit line 101a and the source line 101b are formed of N+ type semiconductor material. If there are holes stored in the floating body 102, they reduce the threshold voltage of the cell to represent data ‘1’. If there are no hole stored in the floating body 102, this condition increases the threshold voltage of the cell to represent data ‘0’.

To write data ‘1’, the front gate 104a is supplied with a positive voltage higher than the threshold voltage of the cell, such as 0.7V to 1V. The bit line 101a is supplied with a positive voltage, such as 2V to 2.5V. The source line 101b is supplied with 0V. This condition turns on the channel under the front gate 104a in saturation mode and causes impact ionization to occur in the bit line 101a junction. This generates electron-hole pairs and inject holes into the floating body 102.

To write data ‘0’. The front gate 104a is supplied with a positive voltage such as 1V to 2V. The bit line 101a or the source line 101b is supplied with a negative voltage such as −1V. This causes P-N forward current to flow from the floating body to the bit line 101a or source line 101b to evacuate the holes stored in the floating body 102.

During read operations, the front gate 104a is supplied with a read voltage between the threshold voltages of the data ‘1’ and ‘0’. The bit line 101a is supplied with a positive voltage such as 0.5V to 1V. The source line 101b is supplied with 0V. A sensing circuit is coupled to the bit line 101a to detect the current to determine the data.

During a hold operation, the back gate 104b is supplied with a negative voltage such as −1V to attract holes into the floating body 102 to increase the data retention time of the cell.

The above-described read and write mechanisms and conditions are exemplary and not limiting. In addition to the described mechanisms, there are many other mechanisms that can be utilized such as band-to-band tunneling (BTBT), gate-induced drain leakage (GIDL), extrinsic bipolar current, impact ionization by intrinsic bipolar current, charge-pumping, direct tunneling, and so on. Using any other mechanisms in the read and write operations of the cell structures according to the invention shall remain in the scope of the invention.

In another embodiment, when the floating body 102 is formed of polysilicon material, electric charges such as electrons may be trapped in the grain boundaries of the polysilicon in the floating body 102. In one embodiment, the floating body 102 has P-type of light doping. The bit line 101a and the source 101b have N+ type of heavy doping. The electrons trapped in the grain boundaries of the polysilicon increase the threshold voltage of the cell.

In another embodiment, the floating body 102 is formed of semiconductor materials that are different from the bit line 101a and the source line 101b. For example, in one embodiment, the bit line 101a and the source line 101b are formed of silicon or polysilicon material and the floating body 102 is formed of silicon germanium (SiGe) or silicon carbide (SiC) material. This configuration forms a heterostructure junction between the two materials and forms a quantum well inside the floating body 102 to store electric charge such as holes. This configuration increases the data retention time of the cell.

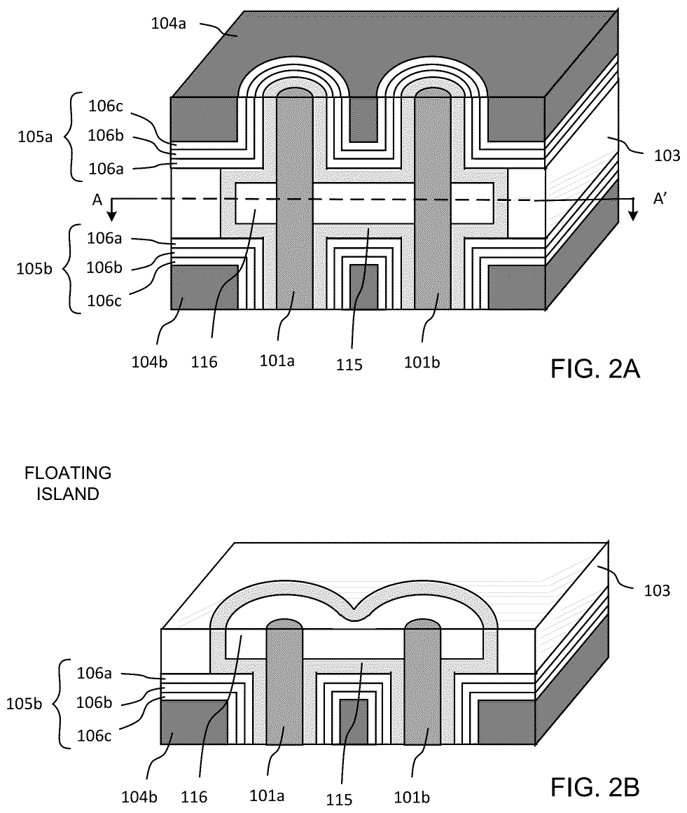

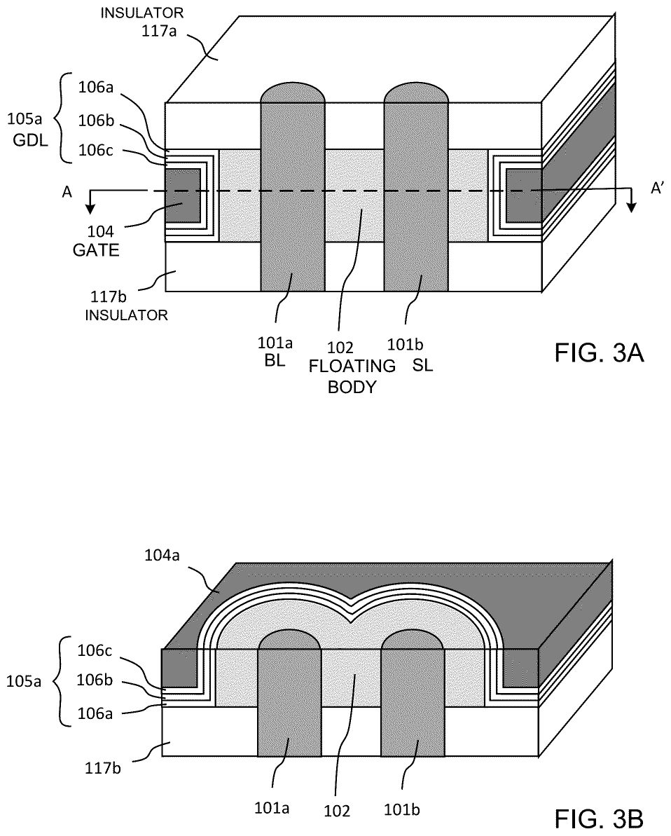

Please notice, the above-described material and structure for the gate dielectric layer 105a and 105b shown in FIGS. 1A-F are applicable to all other embodiments of the cell structures shown in FIGS. 2A-3A. For simplicity, the embodiments shown in FIGS. 2A-3A will be described using oxide-nitride-oxide (ONO) layers for example. However, using any other dielectric layer material and structure shall remain in the scope of the invention.

FIG. 2A shows another embodiment of a cell structure for a 3D NOR-type (or also called AND-type) array according to the invention. FIG. 2B shows a cross-section of the cell structure shown in FIG. 2A along the line A-A′. This embodiment is similar to the embodiment shown in FIGS. 1A-D except that a semiconductor layer 115 comprises material such as silicon, polysilicon, germanium (Ge), indium gallium zinc oxide (IGZO), tungsten-doped indium oxide semiconductor, or any other suitable semiconductor materials, and an insulating layer 116 comprises material such as oxide or nitride. The semiconductor layer 115 forms a channel between the bit line 101a and the source line 101b.

The channel is turned on or off by applying a read voltage to the gates 104a and 104b. For example, assuming the semiconductor layer 115 is formed of N+ type of heavily doped polysilicon, then when the gates 104a and 104b are supplied with a voltage higher than the threshold voltage (Vt) of the cell, the channel of the semiconductor layer 115 will be in accumulation mode to allow electrons to flow between the bit line 101a and the source line 101b. When the gates 104a and 104b are supplied with a voltage lower than the threshold voltage of the cell, the channel will be in depletion mode and thus no electron will flow through it.

In another embodiment, the cell structure shown in FIGS. 2A-B are applicable to floating body cells for DRAM applications. The gate dielectric layers 105a and 105b are formed of thin gate oxide or high-K material such as hafnium oxide (HfO2) as shown in FIG. 1E.

In another embodiment, the cell structure shown in FIGS. 2A-B are applicable to ferroelectric random-access memory (FRAM) or ferroelectric field-effect transistor (FeFET) cells. The gate dielectric layers 105a and 105b comprise a ferroelectric layer and a gate dielectric layer such as 120a and 120b shown in FIG. 1F.

FIG. 3A shows another embodiment of a cell structure for a 3D NOR-type (or also called AND-type) array according to the invention. FIG. 3B shows the cross-section of the cell shown in FIG. 3A taken along the line A-A′. This embodiment is similar to the embodiment shown in FIGS. 1A-D except that insulating layers 117a and 117b comprising material such as oxide or nitride material, and the gate 104 is formed of conductor material such as metal or heavily doped polysilicon and is formed surrounding the floating body 102 as shown. Charge-trapping layers 105a such as oxide-nitride-oxide (ONO) layers as described in FIG. 1A. For example, the charge-trapping layers 105a comprise a tunnel oxide layer 106a, a nitride layer 106b, and a blocking oxide layer 106c, respectively.

In this embodiment, the semiconductor floating body 102 forms a channel between the bit line 101a and the source line 101b. The channel length of the cell transistor is in the range of 1 nm (nanometer) to 1 um (micro-meter), however, any other channel lengths may be used. The channel may be turned on or off by applying a read voltage to the gate 104. For example, assuming the floating body 102 is formed of N+ type of heavily doped polysilicon, when the gate 104 is supplied with a voltage higher than the threshold voltage (Vt) of the cell, the channel of the floating body 102 will be in accumulation mode to allow electrons to flow between the bit line 101a and the source line 101b. When the gate 104 is supplied with a voltage lower than the threshold voltage of the cell, the channel will be in depletion mode thus no electron will flow through it.

In another embodiment, the cell structure shown in FIGS. 3A-B is applicable to floating body cells for DRAM applications. The gate dielectric layers 105a and 105b are formed of thin gate oxide or high-K material such as hafnium oxide (HfO2) as shown in FIG. 1E.

In another embodiment, the cell structure shown in FIGS. 3A-B is applicable to ferroelectric random-access memory (FRAM) or ferroelectric field-effect transistor (FeFET) cells. The gate dielectric layers 105a and 105b comprise a ferroelectric layer and a gate dielectric layer such as 120a and 120b shown in FIG. 1F.

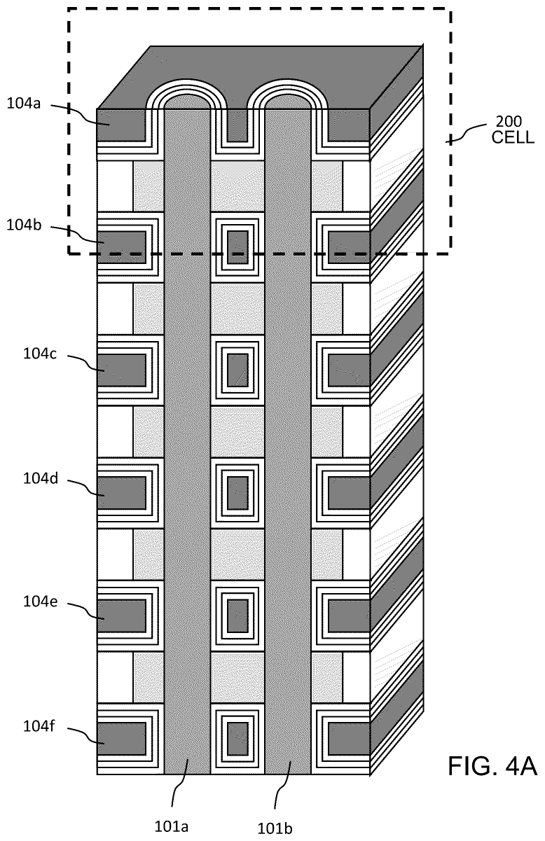

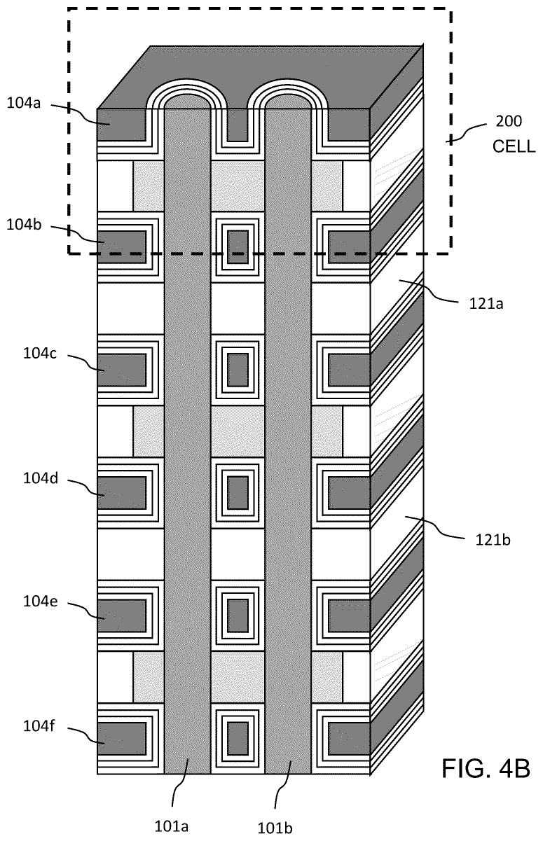

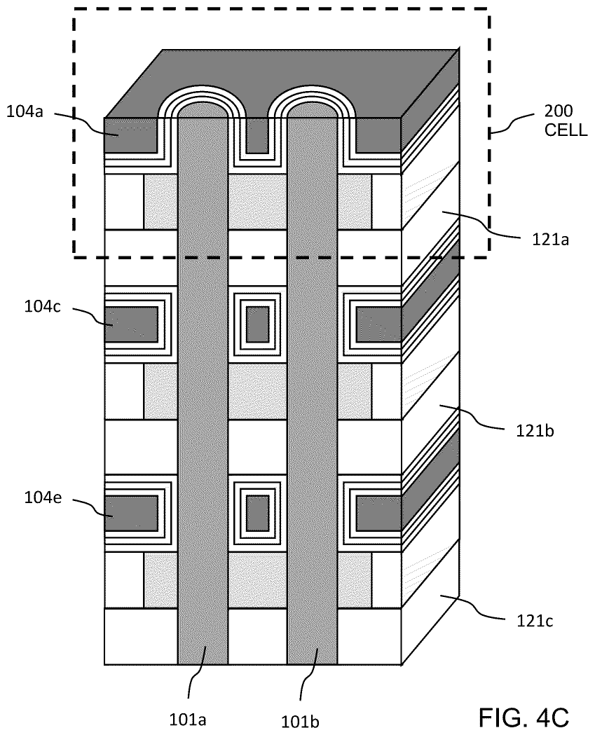

FIG. 4A shows an embodiment of a 3D array structure using the cell structure shown in FIGS. 1A-D according to the invention. For example, the cell 200 can be the cell shown in FIGS. 1A-D. Word line layers 104a to 104f are connected to the gates of the cells. The vertical bit line 101a and source line 101b are connected to multiple cells of the array structure.

FIG. 4B shows another embodiment of a 3D array structure according to the invention. This embodiment is similar to the embodiment shown in FIG. 4A except that insulating layers 121a and 121b comprising material such as oxide or nitride material are formed between the cells.

FIG. 4C shows another embodiment of a 3D array structure to the invention. This embodiment is similar to the embodiment shown in FIG. 4B except that each cell has only a front gate such as front gates 104a, 104c, and 104e. The back gates of the cells are eliminated.

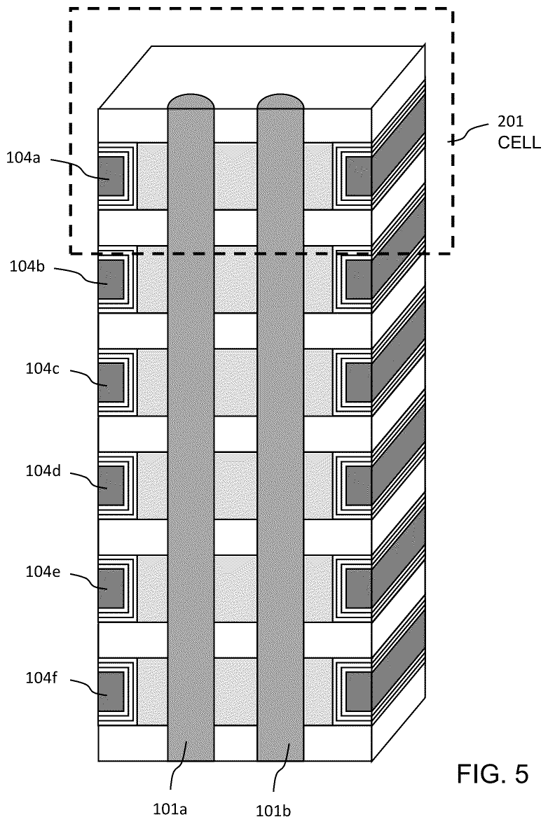

FIG. 5 shows another embodiment of a 3D array structure using the cell structure shown in FIGS. 3A-B according to the invention. A cell 201 is a cell such as the one shown in FIGS. 3A-B. The array structure also includes multiple layers of gates 104a to 104f that form the word lines of the array. Also included are the vertical bit line 101a and source line 101b that are connected to the multiple cells.

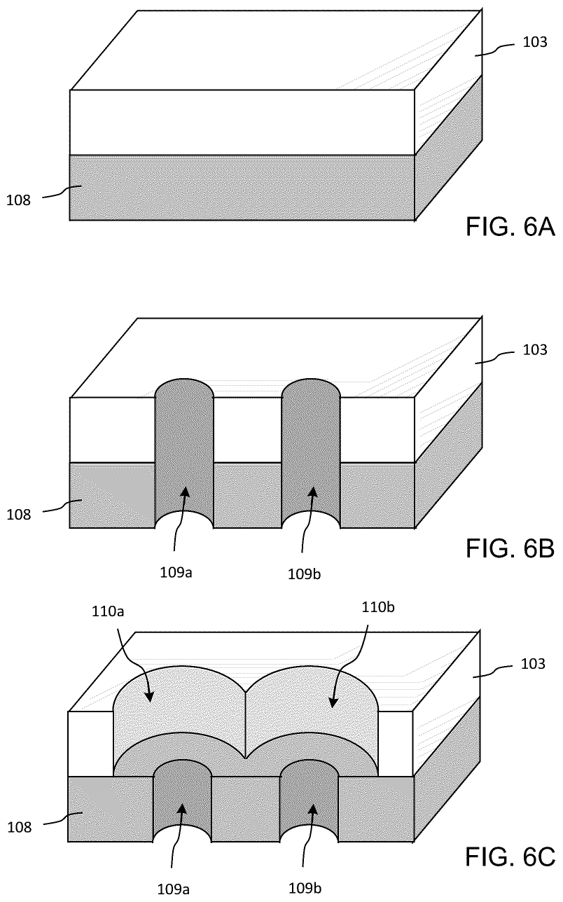

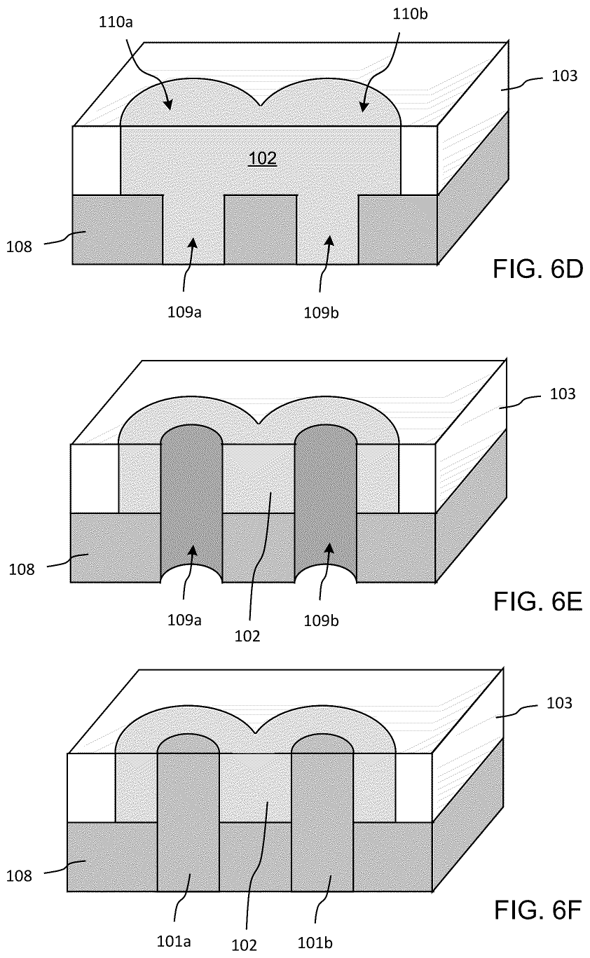

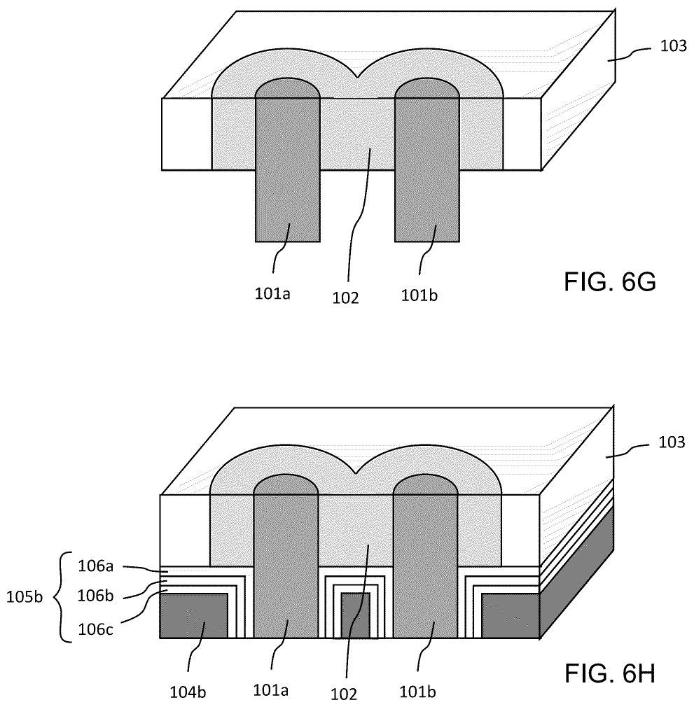

FIGS. 6A-H show an embodiment of process steps used to form the cell structure shown in FIGS. 1A-D according to the invention.

FIG. 6A shows how multiple insulating layers such as insulating layer 103 and sacrificial layers such as sacrificial layer 108 are alternately deposited to form a stack using any suitable deposition processes such as chemical vapor deposition (CVD), physical vapor deposition (PVD), low pressure chemical vapor deposition (LPCVD), plasma-enhanced chemical vapor deposition (PECVD), and many others. The insulating layers 103 and the sacrificial layers 108 have high etching selectivity. In one embodiment, the insulating layer 103 and the sacrificial layer 108 comprise oxide and nitride materials, respectively.

FIG. 6B shows how multiple bit line holes 109a and source line holes 109b are formed. In one embodiment, a photolithographic process is used to define the pattern of the bit line holes 109a and source line holes 109b, and then an anisotropic etching process such as deep trench or dry etch process is used to etch through the multiple insulating layers 103 and sacrificial layers 108 to form the holes 109a-b.

FIG. 6C shows how an isotropic etching process such as wet etch is performed and/or applied through portions of the bit line holes 109a and the source line holes 109b to selectively etch the insulating layer 103 to form recess regions 110a and 110b as shown. In one embodiment, the recess regions 110a and 110b are large enough so that they connect or touch as shown in FIG. 6C.

FIG. 6D shows how the recess regions 110a and 110b and the bit line hole 109a and the source line hole 109b are filled with a semiconductor material 102 that will form a floating body such as silicon (Si), polysilicon, germanium (Ge), indium gallium zinc oxide (IGZO), tungsten-doped indium oxide semiconductor, or any other suitable semiconductor materials.

FIG. 6E shows how an anisotropic etching process such as dry etch is performed to etch the semiconductor inside the bit line hole 109a and the source line hole 109b to form a floating body 102. In one embodiment, the etching process uses the photoresist mask for the bit line hole 109a and the source line 109b formed in the process step shown in FIG. 6E, or in another embodiment, uses the sacrificial layers 108 as hard masks.

FIG. 6F shows how the vertical bit line hole 109a and the source line hole 109b are filled with a conductor material such as metal or heavily doped polysilicon by using an appropriate deposition process.

FIG. 6G shows how an isotropic etching process such as wet etch is performed to selectively remove the sacrificial layer 108.

FIG. 6H shows how a gate dielectric layer 105b formed by charge-trapping layers that comprises a tunnel oxide layer 106a, a nitride layer 106b, and a blocking oxide layer 104c, are formed on the surface of the sidewall of the spaces previously occupied by the sacrificial layer 108 by using a suitable process such as a thin-film deposition process or an atomic layer deposition (ALD) process.

Next, the spaces below the charge-trapping layers are filled with a conductor material such as metal or polysilicon to form gates 104b. As a result, the cell structure shown in FIGS. 1A-D is formed. It should be noted that the process steps shown in FIGS. 6A-H are exemplary and that some process steps may be added, removed, or slightly modified within the scope of the invention.

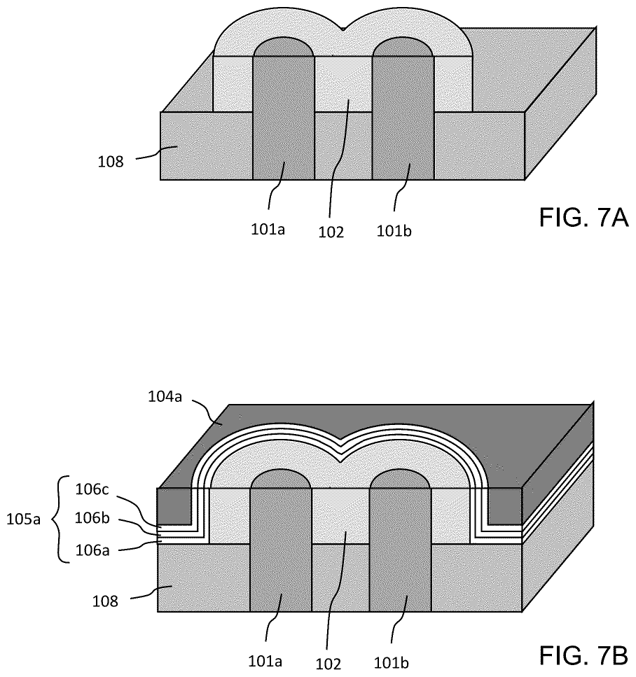

FIGS. 7A-B shows an embodiment of process steps used to form the cell structure shown in FIGS. 3A-B according to the invention.

First, the process steps shown in FIGS. 6A-F are performed to form the cell structure shown in FIG. 6F, however, in the cell structure shown in FIG. 6F the layers are configured such that layer 103 is a sacrificial layer and layer 108 is an insulating layer. In one embodiment, the sacrificial layer 103 and the insulating layer 108 comprise material such as nitride and oxide material, respectively.

FIG. 7A shows how the sacrificial layer 103 is selectively removed by using an isotropic etching process such as wet etch.

FIG. 7B shows how a gate dielectric layer 105 is formed to have charge-trapping layers that comprises a tunnel oxide layer 106a, a nitride layer 106b, and a blocking oxide layer 104c. The gate dielectric layer 105 is formed on the surface of the sidewall of the spaces previously occupied by the sacrificial layers 103 by using a suitable process such as a thin-film deposition process or an atomic layer deposition (ALD) process.

Next, the region or space above the gate dielectric layer 105 is filled with a conductor material such as metal or polysilicon to form the gate 104a. As a result, the cell structure shown in FIGS. 3A-B is formed. It should be noted that the process steps shown in FIGS. 7A-B are exemplary and not limiting and that some process steps may be added, removed, or slightly modified within the scope of the invention.

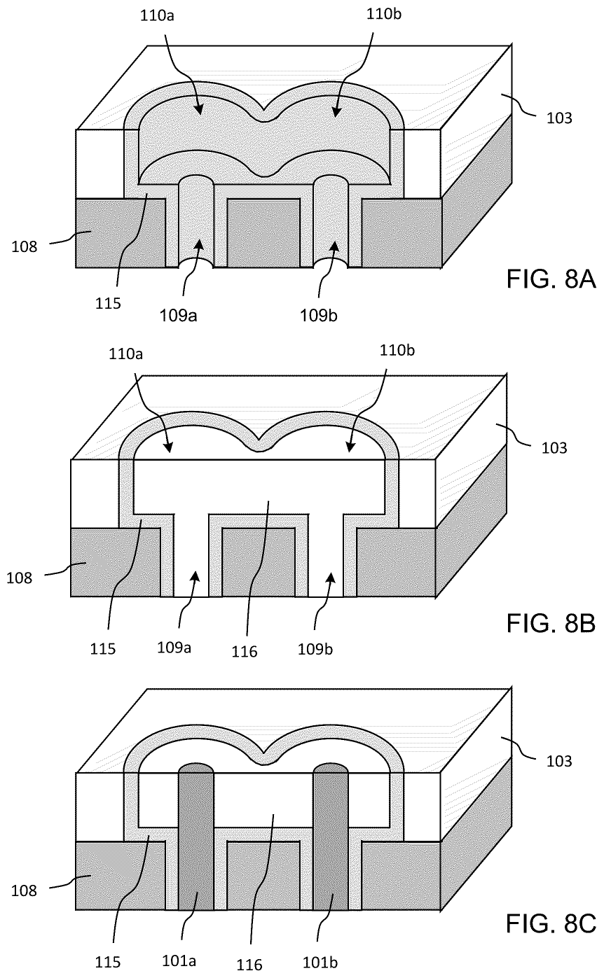

FIGS. 8A-C show another embodiment of process steps to form the cell structure shown in FIGS. 2A-B according to the invention.

First, the process steps shown in FIGS. 6A-F are performed to form the cell structure shown in FIG. 6F, however, in the cell structure shown in FIG. 6F the layers are defined such that layer 103 is a sacrificial layer and layer 108 is an insulating layer. In one embodiment, the sacrificial layer 103 and the insulating layer 108 comprise material such as nitride and oxide material, respectively.

FIG. 8A shows how a semiconductor layer 115 comprising material such as silicon (Si), polysilicon, germanium (Ge), indium gallium zinc oxide (IGZO), tungsten-doped indium oxide semiconductor, or any other suitable semiconductor materials is formed on the surface of the sidewall of the recess regions 110a and 110b and the bit line hole 109a and source line 109b as shown by using suitable processes such as a thin-film deposition process or an atomic layer deposition (ALD) process.

FIG. 8B shows how the recess regions 110a and 110b and the bit line hole 109a and the source line hole 109b are filled with an insulator 116 comprising material such as oxide or nitride material.

FIG. 8C shows how an anisotropic etching process such as dry etch is performed to etch the insulator 116 inside the bit line hole 109a and the source line hole 109b. In one embodiment, the etching process uses the photoresist mask for the bit line hole 109a and the source line hole 109b formed in previous process step or uses the sacrificial layers 108 as a hard mask. Next, the bit line hole 109a and the source line hole 109b are filled with a conductor material such as metal or heavily doped polysilicon material to form a bit line 101a and a source line 101b.

After the above processes, the processes shown in FIGS. 6G-H are performed to remove the sacrificial layer 108 and then form the gate dielectric layer 105a and the gate 104b. The reader is referred to FIGS. 6G-H for a detailed description.

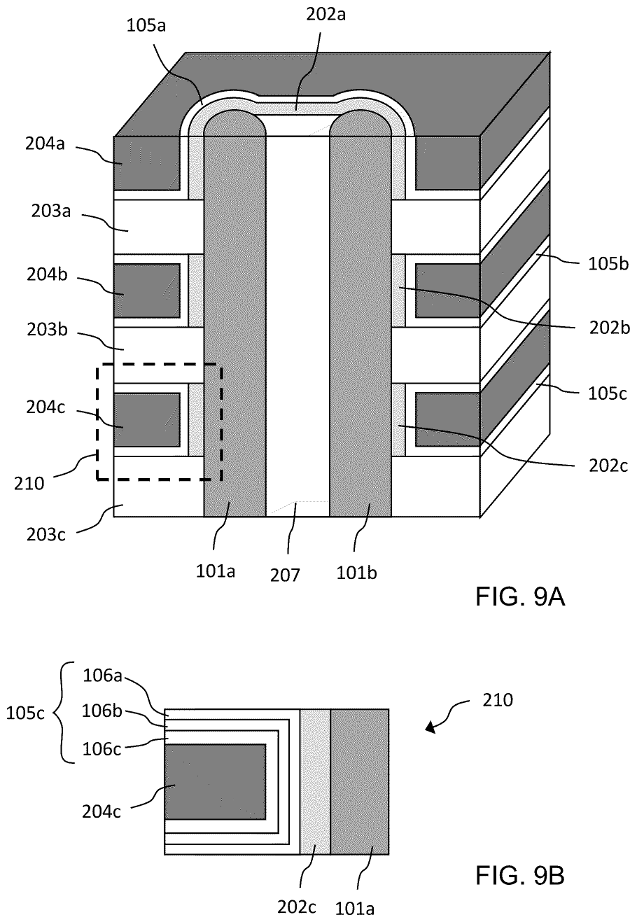

FIG. 9A shows another embodiment of a cell structure for a 3D NOR-type (or also called AND-type) array according to the invention. The cell structure shown in FIG. 9A includes a vertical bit line 101a and a vertical source line 101b that are formed of conductor material such as metal or heavily doped semiconductor material such as N+ or P+ polysilicon material. In another embodiment, a metal core is formed in the center of the bit line 101a and the source line 101b to reduce the resistance of the bit line 101a and the source line 101b.

The cell structure shown in FIG. 9A also includes channels 202a to 202c that are formed of semiconductor layers such as silicon, polysilicon, germanium (Ge), indium gallium zinc oxide (IGZO), tungsten-doped indium oxide semiconductor, or any other suitable semiconductor materials. An insulator 207 is proved that comprises material such as oxide or nitride material. Word line layers 204a to 204c are provided that are formed of conductor material such as metal or heavily doped polysilicon material. The word line layers 204a to 204c also form the gates of the cell transistors. Also provided are insulating layers 203a to 203c comprising material such as oxide or nitride material and gate dielectric layers 105a to 105c. Depending on the cell type and technology, the gate dielectric layers 105a to 105c comprise different materials and structure. For example, in one embodiment, the gate dielectric layers 105a to 105c are charge-trapping layers such as oxide-nitride-oxide (ONO) layers.

FIG. 9B shows a detailed embodiment of the charge-trapping layers 105c as shown in the region 210 illustrated in FIG. 9A. The charge trapping layer 105c comprises three layers 106a to 106c. The layer 106a is a tunnel oxide layer which is thin enough to allow electrons to tunnel through when a high electric field is applied. The layer 106b is a nitride layer that traps electrons or holes for data storage. The layer 106c is a blocking oxide which is thick enough to prevent electrons tunneling through to the word line 204c. In another embodiment, the layer 106c is a tunnel oxide layer and the layer 106a is a blocking oxide layer. In this embodiment, during programming, the electrons or holes are injected from the selected word line 204c to the nitride layer 106b.

In one embodiment, the cells are programmed and erased by using Fowler-Nordheim (FN) mechanism. The cell is programmed by applying high voltages to the word lines 204a to 204c or to the bit line 101a and the source line 101b to inject electrons into the charge-trapping layers 105a to 105c. The cell is erased by applying high voltages to the bit line 101a and the source line 101b to inject holes into the charge-trapping layers 105a to 105c to neutralize the trapped electrons. Electrons trapped in the charge-trapping layers 105a to 105c alter the threshold voltage (Vt) of the cells to represent the stored data.

It should be noted that although ONO layers 106a to 106c are used as an example, the charge-trapping layers 105a to 105c can comprise any suitable number of nitride and oxide layers. For example, in another embodiment, the charge-trapping layers 105a to 105c comprise oxide-nitride-oxide-nitride-oxide (ONONO) layers. These variations are within the scope of the invention.

In another embodiment, the charge trapping layers 105a to 105c comprise only one nitride layer 106b and one blocking oxide layer 106c. In this embodiment, because the tunnel oxide layer 106a is removed, the tunneling barrier is reduced. Therefore, the program time and program voltage are also reduced. However, the electrons trapped in the nitride layer 106b may escape in much shorter time, thus the data needs to be periodically re-programmed (called ‘refresh’). This embodiment may be used as a DRAM-replacement application.

In another embodiment, the cell structure is applied to ferroelectric random-access memory (FRAM) cells. In this embodiment, the gate dielectric layers 105a to 105c comprise only two layers such as layer 106a and layer 106b. The layer 106c is eliminated. The layer 106b is a ferroelectric layer such as lead zirconate titanate (PZT) or hafnium oxide (HfO2) in orthorhombic crystal phase, or hafnium zirconium oxide (HfZrO2). The layer 106a is a dielectric layer (or called buffer layer) such as oxide (SiO₂) or hafnium oxide (HfO2). By applying high voltages to the word lines 204a to 204c or the bit line 101a and the source line 101b, the polarity of the atoms of the ferroelectric material are changed. This alters the threshold voltage (Vt) of the cells to represent the stored data.

For another embodiment of resistive random-access memory (RRAM), the gate dielectric layers 105a to 105c comprise an adjustable resistive layer such as hafnium oxide (HfOx), titanium oxide (TiOx), and tantalum oxide (TaOx). In another embodiment of phase-change memory (PCM), the gate dielectric layers 105a to 105c are formed of multiple layers comprising at least one phase-change layer such as Germanium Antimony Tellurium alloy or chalcogenide glass, Ge2Sb2Te5 (GST).

For an embodiment of a magneto resistive random-access memory (MRAM), the gate dielectric layers 105a to 105c comprise multiple layers including ferromagnetic material such as iron-nickel (NiFe) or iron-cobalt (CoFe) alloys. It should be noted that the materials of the gate dielectric layers 105a to 105c described above are just some examples. In other embodiments, any other suitable materials can be used in the gate dielectric layers 105a to 105c and these embodiments are within the scope of the invention.

In an embodiment, the word lines 204a to 204c are coupled to the channels 202a to 202c. When the selected word lines 204a to 204c are supplied with a voltage higher than the threshold voltage (Vt), the selected channels 202a to 202c are turned on to conduct current from the bit line 101a to the source line 101b. If the cell's threshold voltage is higher than the applied word line voltage, the channel may not be turned on, thus there is no current flowing. A sensing circuit can be connected to the bit line 101a to detect the current to determine the read data.

In an embodiment, the channels 202a to 202c are isolated by the insulating layers 203a to 203c. This prevents leakage current from leaking from the unselected cells. If the channels 202a to 202c are vertically connected to form a continuous layer, leakage current will occur from the bit line 101a to the source line 101b through the channel layer between the word lines 204a to 204c.

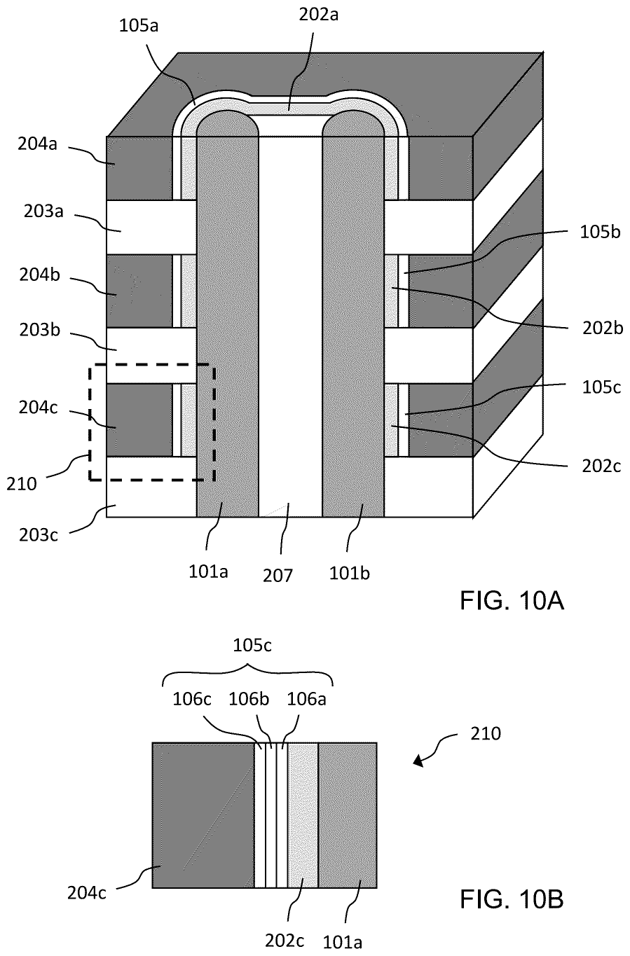

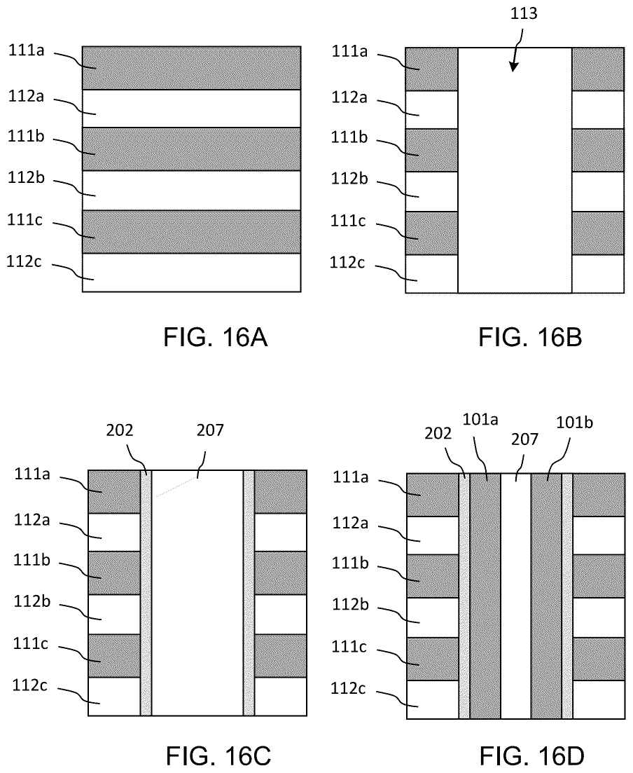

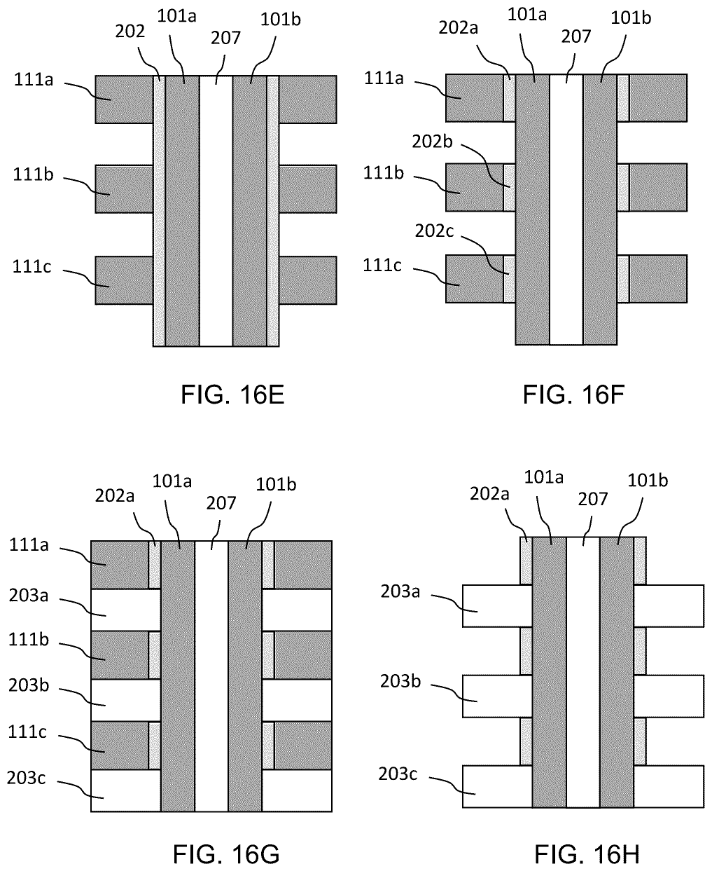

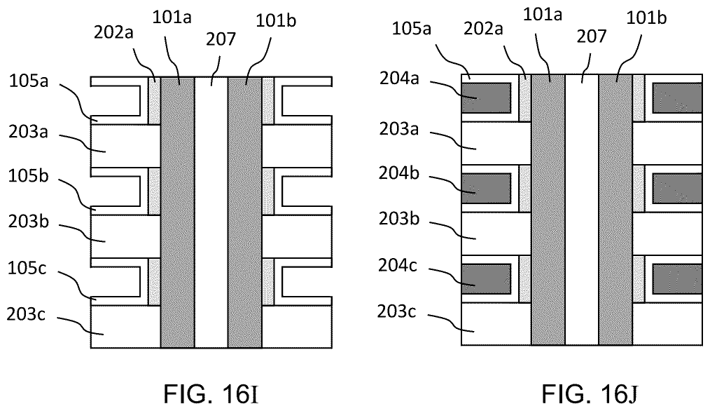

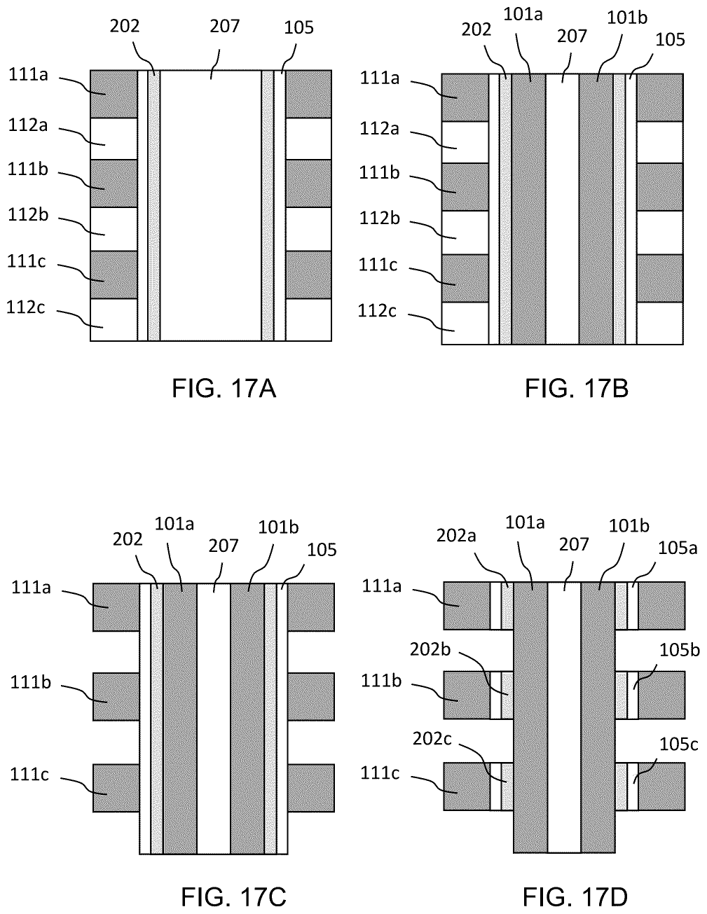

FIG. 10A shows an embodiment of a cell structure for a 3D NOR-type (or also called AND-type) array according to the invention. FIG. 10B shows a detailed embodiment of the cell structure of the gate dielectric layer 105c within the region 210. This embodiment is similar to the embodiment shown in FIG. 9A except that the gate dielectric layers 105a to 105c are formed in different patterns or shapes. These two different patterns or shapes are formed by different process flows. FIGS. 16A-J and FIGS. 17A-D illustrate a detailed description of the process flows.

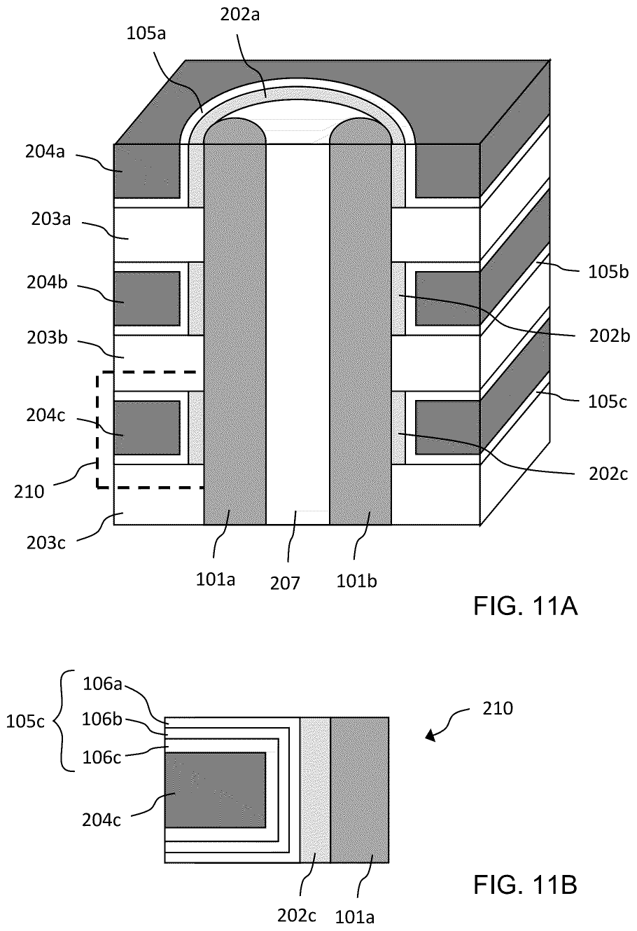

FIG. 11A shows an embodiment of a cell structure for a 3D NOR-type (or also called AND-type) array according to the invention. FIG. 11B shows detailed embodiment of the cell structure of the gate dielectric layer 105c as shown in the region 210. This embodiment is similar to the embodiment shown in FIG. 9A except that the insulator 207 is formed in different patterns or shapes.

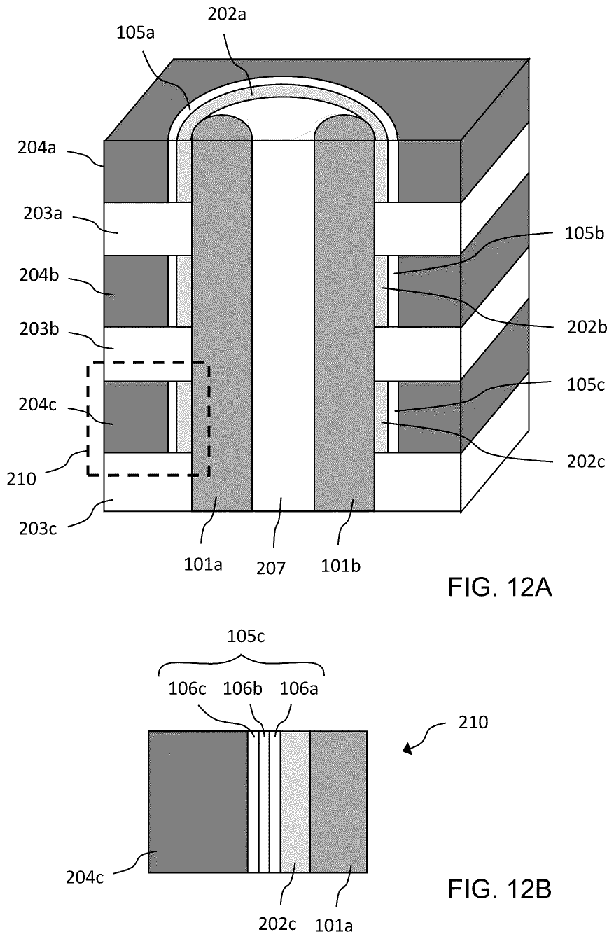

FIG. 12A shows an embodiment of a cell structure for a 3D NOR-type (or also called AND-type) array according to the invention. FIG. 12B shows detailed embodiment of the structure of the gate dielectric layer 105c as shown in the region 210. This embodiment is similar to the embodiment shown in FIG. 11A except that the gate dielectric layers 105a to 105c are formed in different patterns or shapes.

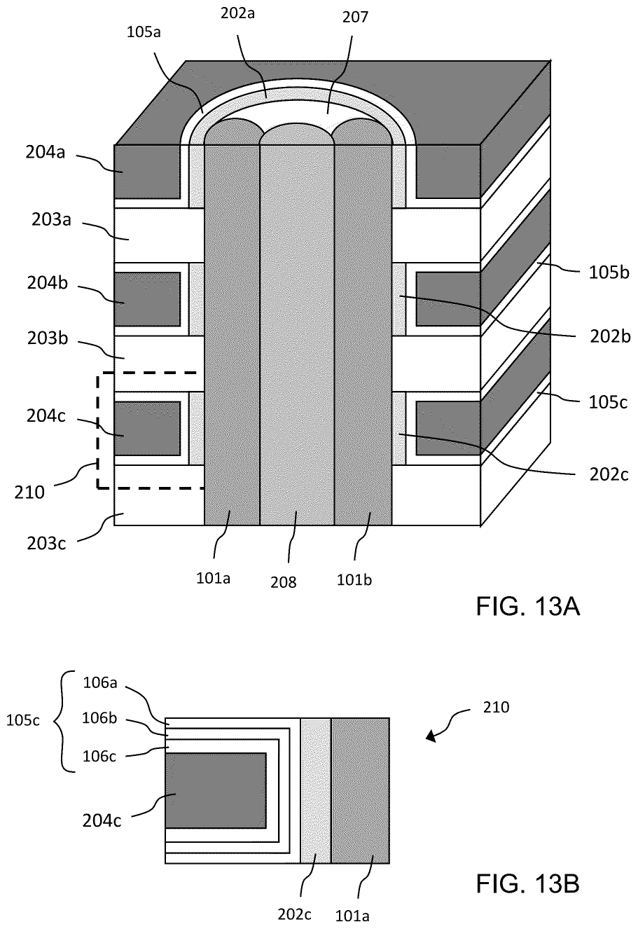

FIG. 13A shows an embodiment of a cell structure for a 3D NOR-type (or also called AND-type) array according to the invention. FIG. 13B shows detailed embodiment of the structure of the gate dielectric layer 105c as shown in the region 210. This embodiment is similar to the embodiment shown in FIG. 11A except that an additional insulator 208 is formed in the center of the insulator 207 to isolate the bit line 101a and the source line 101b.

In one embodiment, the insulator 208 is formed after the bit line 101a and the source line 101b are formed. The insulator 208 is formed by using an anisotropic etching process such as deep trench to etch a vertical hole and then deposit an insulator material such as oxide or nitride material to fill the hole. The etching solution is configured to etch the materials of the insulator 207 and the bit line 101a and the source line 101b.

In another embodiment, the insulator 208 is formed before the bit line 101a and the source line 101b are formed. In this embodiment, the insulators 207 and 208 have different etching selectivity. After the insulators 207 and 208 are formed, an anisotropic etching process such as deep trench or dry etch is performed to selectively etching the insulator 207 to form two vertical holes for the bit line 101a and the source line 101b. The etching solution that is utilized does not etch the insulator 208. After that, the two holes are filled with conductor material to form the bit line 101a and the source line 101b.

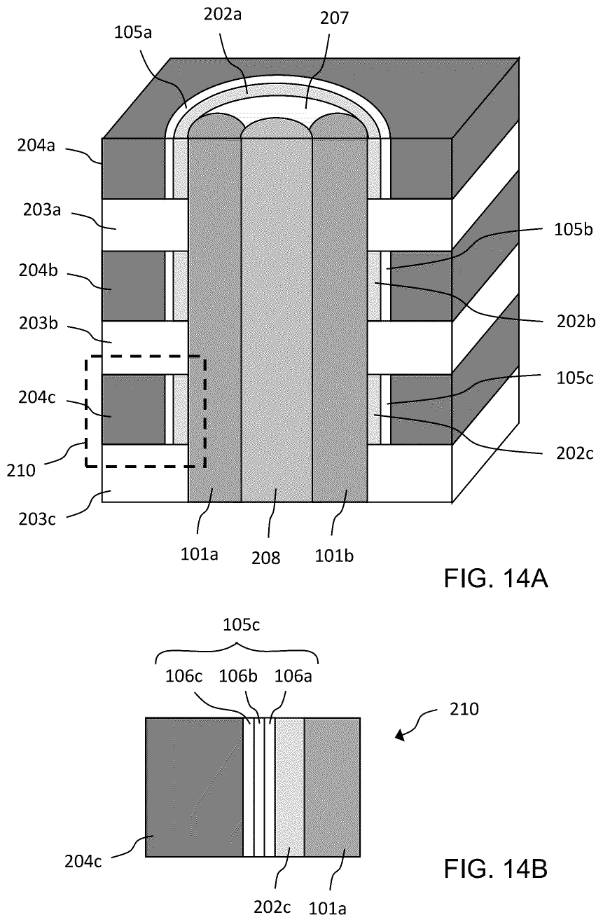

FIG. 14A shows an embodiment of a cell structure for a 3D NOR-type (or also called AND-type) array according to the invention. FIG. 14B shows detailed embodiment of the structure of the gate dielectric layer 105c as shown in the region 210. This embodiment is similar to the embodiment shown in FIG. 13A except that the gate dielectric layers 105a to 105c are formed in different patterns or shapes.

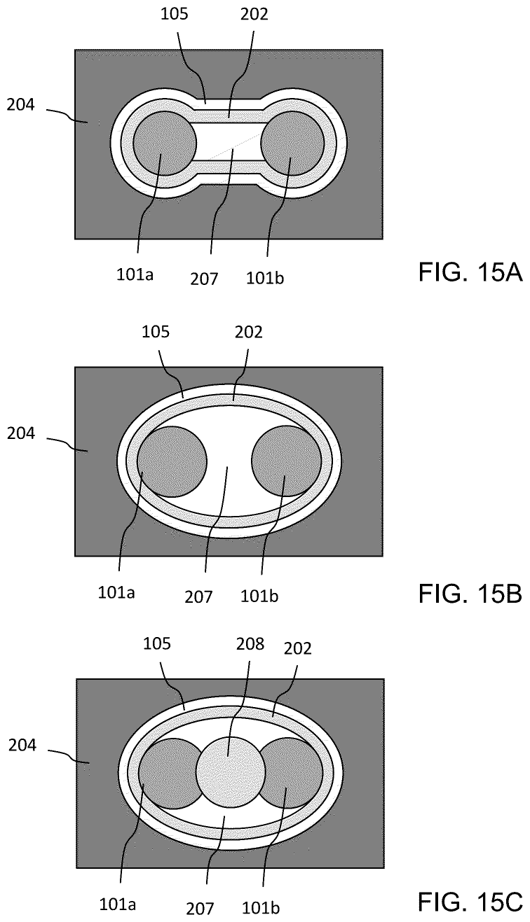

FIGS. 15A-C show comparisons of top views of the three cell structures shown in FIG. 9A, FIG. 11A, and FIG. 13A, respectively. The reader is referred to the descriptions of FIG. 9A, FIG. 11A, and FIG. 13A for detailed descriptions of the cell structures.

FIGS. 16A-J shows an embodiment of process steps configured to form the cell structure shown in FIG. 11A according to the invention. It should be noted that the described process steps are applicable with minor modifications to form the other cell structure embodiments shown in FIGS. 10A-14A. For simplicity and clarity, the process steps for these other embodiments will not be shown but the minor modifications and variations are within the scope of the invention.

FIG. 16A shows how multiple first sacrificial layers 111a to 111c and second sacrificial layers 112a to 112c are alternately deposited to form a stack. In one embodiment, the first sacrificial layers 111a to 111c and the second sacrificial layers 112a to 112c have different etching selectivity. For example, in one embodiment, the first sacrificial layers 111a to 111c comprise oxide material having a first etching selectivity and the second sacrificial layers 112a to 112c comprise nitride material having a second etching selectivity.

FIG. 16B shows how one or more vertical holes 113 are patterned on the stack by using photolithography steps and then the holes are formed by using an anisotropic etching process such as deep trench process to etch through the multiple layers of the stack.

FIG. 16C shows how a semiconductor layer 202 comprising material such as polysilicon or silicon material is formed on the surface of the sidewall of the hole 113 by using any suitable deposition processes such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or an epitaxial growth process (for single-crystalline silicon). Next, the hole 113 is filled with insulator material 207 such as oxide or nitride material by using CVD or any other suitable deposition processes.

FIG. 16D shows how the vertical bit line 101a and source line 101b are formed by first forming two vertical holes using photolithography steps and then etching the holes by using an anisotropic etching process such as deep trench or dry etch process to selectively etch the insulator 207. The etching solution utilized does not etch the semiconductor layer 202. Next, the holes are filled with conductor materials such as metal or heavily doped polysilicon material to form the vertical bit line 101a and source line 101b.

FIG. 16E shows how the second sacrificial layers 112a to 112c are selectively removed by using an isotropic etching process such as wet etch. The etching solution utilized does not etch the first sacrificial layers 111a to 111c.

FIG. 16F shows how an isotropic etching process such as wet etch is performed to selectively etch portions of the semiconductor layer 202 through the spaces that are previously occupied by the second sacrificial layers 112a to 112c to form individual channel layers 202a to 202c. The etching solution utilized does not etch the first sacrificial layers 111a to 111c and the material of the bit line 101a and the source line 101b.

FIG. 16G shows how a deposition process such as ALD, CVD, PVD, or any other suitable deposition processes is performed to fill the spaces that were previously occupied by the second sacrificial layers 112a to 112c with insulator such as oxide or nitride material to form the insulating layers 203a to 203c. The insulating layers 203a to 203c have different etching selectivity from the first sacrificial layers 111a to 111c.

FIG. 16H shows how the first sacrificial layers 111a to 111c are selectively removed by using an isotropic etching process such as wet etch. The etching solution utilized does not etch the channel layers 202a to 202c and the insulating layers 203a to 203c.

FIG. 16I shows how the gate electric layers 105a to 105c are formed on the surface of the sidewall of the spaces that were previously occupied by the first sacrificial layers 111a to 111c by using atomic layer deposition (ALD), plasma-enhanced atomic layer deposition (PE-ALD), chemical vapor deposition (CVD), or any other suitable deposition processes. Depending on the materials and structures of the gate dielectric layers 105a to 105c, the deposition process is performed one or more times to form multiple-layer structures. The reader is referred to the description of FIG. 1A for a detailed description of the materials and structures of the gate dielectric layers 105a to 105c.

FIG. 16J shows how a deposition process such as ALD, CVD, PVD, or any other suitable deposition processes are performed to fill the spaces that were previously occupied by the first sacrificial layers 111a to 111c with conductor material such as metal or polysilicon material to form the word line layers 204a to 204c. As a result of the above operations, the cell array structure shown in FIG. 11A is formed.

FIGS. 17A-D show an embodiment of process steps configured to form the cell structure shown in FIG. 12A according to the invention. After the process steps shown in FIG. 16B are performed, a gate dielectric layer 105 and a semiconductor layer 202 are sequentially formed on the surface of the sidewall of the hole 113 by using a deposition process as described with reference to FIGS. 16A-J. Next, the remaining unfilled portion of the hole 113 is filled with an insulator 207 by using a deposition process. It should be noted that the thickness of the layer 105 and layer 202 are in the range of 5-20 nanometers (nm), however, the thicknesses may be further reduced in future implementations.

FIG. 17B shows how the bit line 101a and the source line 101b are formed by using the process steps described with reference to FIG. 16D.

FIG. 17C shows how the second sacrificial layers 112a to 112c are selectively etched by using the process steps described with reference to FIG. 16E.

FIG. 17D shows how an isotropic etching process such as wet etch is performed to selectively etch the gate dielectric layer 105 and the semiconductor layer 202 through the spaces that were previously occupied by the second sacrificial layers 112a to 112c to form individual gate dielectric layers 105a to 105c and semiconductor layers 202a to 202c. Depending on the selectivity of the etching solution utilized, the etching process is performed once or twice. When performed twice, the first etching may etch the gate dielectric layer 105 and the second etching may etch the semiconductor layer 202.

Next, the spaces previously occupied by the second sacrificial layers 112a to 112c shown in FIG. 17B are filled with insulator material such as oxide material to form the cell array structure shown on FIG. 12A.

It should be noted that the process steps shown in FIGS. 16A-J and FIGS. 17A-D are exemplary and intended to demonstrate selected embodiments of the invention. It is obvious that the process steps can be modified, added, or removed and these variations and modifications are within the scope of the invention.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A 3D cell structure, comprising:
a vertical bit line (BL);
a vertical source line (SL);
a floating body surrounding and connected to a portion of the BL and a portion of the SL and filling any space in between the BL and SL;
an insulator coupled to and surrounding the floating body;
a first gate dielectric layer coupled to a top surface of the insulator and the floating body, and surrounding top portions of the BL and the SL;
a second gate dielectric layer coupled to a bottom surface of the insulator and the floating body, and surrounding bottom portions of the BL and the SL;
a front gate connected to a top surface of the first gate dielectric layer; and
a back gate connected to a bottom surface of the second gate dielectric layer.

2. The 3D cell structure of claim 1, wherein the BL and SL comprises heavily doped N+ or P+ polysilicon semiconductor material.

3. The 3D cell structure of claim 1, wherein the BL and SL comprises metal cores.

4. The 3D cell structure of claim 1, wherein the floating body comprises a lightly doped semiconductor material having an opposite type of doping from the BL and SL.

5. The 3D cell structure of claim 1, wherein the floating body comprises a heavily doped semiconductor material having a same type of doping as the BL and SL.

6. The 3D cell structure of claim 1, wherein the insulator comprises oxide or nitride material.

7. The 3D cell structure of claim 1, wherein the first and second gate dielectric layers comprise a thin oxide layer or Hi-K material.

8. The 3D cell structure of claim 1, wherein the first and second gate dielectric layers comprise charge-trapping layers selected from a set comprising oxide-nitride-oxide (ONO) layers, oxide-nitride-oxide-nitride-oxide (ONONO) layers, and oxide-nitride (ON) layers.

9. The 3D cell structure of claim 1, wherein the front gate and the back gate comprise metal or heavily doped polysilicon material.

10. The 3D cell structure of claim 1, wherein the BL and SL are parallel to each other and form a channel length having a range of 1 nm (nanometer) to 1 um (micro-meter).

11. A 3D cell structure, comprising:
a vertical bit line (BL);
a vertical source line (SL);
a floating body surrounding and connected to a portion of the BL and a portion of the SL and filling any space in between the BL and SL;
a gate dielectric layer coupled to and surrounding the floating body;
a gate surrounding the gate dielectric layer;
a first insulating layer coupled to a top surface of the gate dielectric layer and the floating body, and surrounding top portions of the BL and the SL; and
a second insulating layer coupled to a bottom surface of the gate dielectric layer and the floating body, and surrounding bottom portions of the BL and the SL.

12. The 3D cell structure of claim 11, wherein the BL and SL comprises heavily doped N+ or P+ polysilicon semiconductor material.

13. The 3D cell structure of claim 11, wherein the BL and SL comprises metal cores.

14. The 3D cell structure of claim 11, wherein the floating body comprises a lightly doped semiconductor material having an opposite type of doping from the BL and SL.

15. The 3D cell structure of claim 11, wherein the floating body comprises a heavily doped semiconductor material having a same type of doping as the BL and SL.

16. The 3D cell structure of claim 11, wherein the first and second insulating layers comprise oxide or nitride material.

17. The 3D cell structure of claim 11, wherein the gate comprises metals or heavily doped semiconductor material.

18. The 3D cell structure of claim 11, wherein the gate dielectric layer comprises charge-trapping layers selected from a set comprising oxide-nitride-oxide (ONO) layers, oxide-nitride-oxide-nitride-oxide (ONONO) layers, and oxide-nitride (ON) layers.

19. The 3D cell structure of claim 11, wherein the BL and SL are parallel to each other and form a channel length having a range of 1 nm to 1 um (micro-meter).

20. The 3D cell structure of claim 11, wherein the 3D cell structure forms a 3D NOR-type cell.
